(19) United States
(12) Patent Application Publication
(10) Pub. No.: US 2010/0019239 A1
(43) Pub. Date: Jan. 28, 2010

(54) METHOD OF FABRICATING ZTO THIN FILM, THIN FILM TRANSISTOR EMPLOYING THE SAME, AND METHOD OF FABRICATING THIN FILM TRANSISTOR

(75) Inventors: Woo Seok Cheong, Daejeon (KR); Sung Min Yoon, Daejeon (KR); Jae Heon Shin, Daejeon (KR); Chi Sun Hwang, Daejeon (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon (KR)

(21) Appl. No.: 12/359,149

(22) Filed: Jan. 23, 2009

(30) Foreign Application Priority Data
Jul. 23, 2008 (KR) 10-2008-0071769
Nov. 14, 2008 (KR) 10-2008-0113381

(51) Int. Cl. H01L 29/786; H01L 21/20

(52) U.S. Cl. 257/43; 438/104; 257/57; 257/E21.09; 257/E29.273; 257/E29.296

(57) ABSTRACT

Provided are a method of fabricating a zinc-tin-oxide (ZTO) thin film, a thin film transistor employing the same, and a method of fabricating a thin film transistor. The method of fabricating a ZTO thin film includes depositing zinc oxide and tin oxide at a deposition temperature of 450° C. or lower so that a zinc-to-tin atomic ratio is 4:1 or greater, to form an amorphous ZTO thin film. In the thin film transistor, the ZTO thin film is used as a channel layer.

### CROSS-REFERENCE TO RELATED APPLICATION

This application claims priority to and the benefit of Korean Patent Application Nos. 10-2008-0071769 and 10-2008-0113381, filed Jul. 23, 2008 and Nov. 14, 2008, the disclosure of which is incorporated herein by reference in its entirety.

### BACKGROUND

1. Field of the Invention

The present invention relates to a method of fabricating a ZTO thin film, a thin film transistor employing the same, and a method of fabricating a thin film transistor. More specifically, the present invention relates to a method of fabricating an amorphous ZTO thin film in which material and process are optimized to enable formation in a low-temperature process with high-reliability, a thin film transistor employing the same, and a method of fabricating a thin film transistor.

This work was partly supported by the IT R&D program of MIC/IITA [2006-S-079-03, Smart Window Using Transparent Electronic Device from Oct. 1, 2006 to Feb. 28, 2011, Research Administering Institute: Electronics & Telecommunications Research Institute] conducted as an IT R&D program for the Ministry of Knowledge Economy/Institute for Information and Technology Advancement (Republic of Korea).

2. Discussion of Related Art

In fabricating a thin film transistor, materials used to form a channel layer largely include ZnO-based material, non-ZnO-based material and silicon-based material. Following is a detailed description of these materials.

### (1) ZnO-Based Material

In order to enhance performance when a channel layer is formed using ZnO-based material, methods of adjusting a ratio of zinc to oxygen (Zn/O) have been developed. Such methods include, for example, a structural approach in which a band-gap is adjusted by substituting La, Ba, Sr, etc., and adjustment through post-processes including low-temperature annealing and laser annealing.

Also, research aimed at improving deteriorated characteristics resulting from a polycrystalline structure of ZnO in ZnO-based material is underway. For example, characteristics are improved through single crystallization method such as a grain growth method and a low-temperature molecular beam epitaxy (MBE) process, or amorphization method using quaternary materials including indium, gallium, zinc, and oxygen. However, the quaternary materials including indium, gallium, zinc, and oxygen have been patented by Hosono, Japan, and thus use of them may require a license.

There has been extensive research into the improvement of characteristics by adjusting the concentration of N-type and P-type carriers when a channel layer is formed using ZnO-based material. For example, a single-element doping method or a low-cost implantation method may be employed, a three-component compound semiconductor, e.g., ZnSnO, MgZnO or CdZnO may be used, and there is plenty of room for more research regarding additional substitutions in three-component compound semiconductors.

### (2) Non-ZnO-Based Material

Non-ZnO-based material includes In—Ga—Zn—O type amorphous semiconductor and individual oxide semiconductors such as In₂O₃ and SnO₂. In—Ga—Zn—O type amorphous semiconductor is unlikely to be free from the original patent of Hosono. While individual oxide semiconductors such as In₂O₃ and SnO₂ have inferior characteristics to ZnO, they have not undergone sufficient research and there is room for improvement of their characteristics by composition adjustment and doping substitution. Non-ZnO-based materials include opaque semiconductors such as CdS, ZnS, ZnSe, etc., whose characteristics are applicable to active matrix organic light emitting diodes (AM OLED), but whose opacity is technical restricting.

### (3) Silicon-Based Material

Devices based on amorphous silicon and polycrystalline silicon are being realized. While mobility of an amorphous silicon transistor is as low as 1 cm/Vs, and that of a polycrystalline silicon transistor is as high as 100 cm/Vs, problems of device uniformity are on the rise.

As described above, thin film transistors using ZnO-based material, non-ZnO-based material, and silicon-based material exhibit the following problems.

A ZnO-based thin film transistor's characteristics are susceptible to changes in humidity, annealing process, and manufacturing process, and thus it has problems of reliability. Further, the transistor has a crystalline channel which may raise problems of device uniformity. Moreover, device deformation caused by current and light may be significant.

Further, in the case of a thin film transistor employing an IGZO channel in which indium and gallium oxides are applied to ZnO, indium and gallium are relatively scarce and therefore costly materials.

In a silicon-based thin film transistor, in particular, amorphous silicon, mobility is low, and with polycrystalline silicon, uniformity may be a problem to creation of a large panel. In particular, the amorphous silicon transistor is vulnerable to instability depending on current.

In general, an oxide thin film transistor may be vulnerable to instability depending on current due to the inside of a channel thin film or an interface with a gate insulating layer.

In addition, a thin film transistor using ZnS, ZnSe, CdS, etc. is opaque and thus may not be applicable to transparent electronic devices.

In the course of research into thin film transistors, the present inventors found that when an optimized zinc oxide : silicon oxide composition ratio is used to form an amorphous ZTO thin film, a process is optimized to form a channel layer using the amorphous ZTO thin film, and a process of forming a gate insulating layer that at least partially forms an interface with a channel layer is optimized, high-reliability can be ensured with a low-temperature process. These findings led to the completion of the present invention.

### SUMMARY OF THE INVENTION

The present invention is directed to a method of fabricating a zinc-tin-oxide (ZTO) thin film that is used for a channel layer of a thin film transistor.

The present invention is also directed to a thin film transistor in which a ZTO thin film having an optimal composition is applied to a channel layer to ensure high-reliability.

The present invention is further directed to a method of fabricating a thin film transistor in which fabricating processes including forming a ZTO channel layer are optimized to ensure high-reliability.

One aspect of the present invention provides a method of fabricating a ZTO thin film including depositing zinc oxide and tin oxide at a deposition temperature of 450° C. or lower to form an amorphous ZTO thin film, wherein a zinc-to-tin atomic ratio is 4:1 or greater.

The method may further include post-annealing the ZTO thin film at a temperature of 150° C. to 450° C.

Another aspect of the present invention provides a thin film transistor including: source and drain electrodes, a channel layer, a gate insulating layer and a gate electrode that are formed on a substrate, wherein the channel layer is an amorphous ZTO thin film formed by depositing zinc oxide and tin oxide at a deposition temperature of 450° C. or lower so that a zinc-to-tin atomic ratio is 4:1 or greater.

The thin film transistor may have a top gate coplanar structure in which source and drain electrodes, a channel layer, a gate insulating layer, and a gate electrode are sequentially formed on a substrate, a top gate staggered structure in which a channel layer, source and drain electrodes, a gate insulating layer and a gate electrode are sequentially formed on a substrate, a bottom gate coplanar structure in which a gate electrode, a gate insulating layer, source and drain electrodes, and a channel layer are sequentially formed on a substrate, or a bottom gate staggered structure in which a gate electrode, a gate insulating layer, a channel layer and source and drain electrodes are sequentially formed on a substrate.

A gate insulating layer of the thin layer transistor is deposited using alumina, silicon nitride or silicon oxide, in the case of a top gate structure, the insulating layer may be deposited at a temperature of 450° C. or lower, and more preferably, it may be post-annealed at a temperature of 150° C. to 450° C. after deposition.

Still another aspect of the present invention provides a method of fabricating a thin film transistor in which source and drain electrodes, a channel layer, a gate insulating layer, and a gate electrode are formed on a substrate, comprising: depositing zinc oxide and tin oxide at a deposition temperature of 450° C. or lower so that a zinc-to-tin atomic ratio is 4:1 or greater to form an amorphous ZTO channel layer; and patterning the ZTO channel layer.

The gate insulating layer that is at least partially in contact with the ZTO channel layer may be deposited using alumina, silicon nitride or silicon oxide, and may be deposited at a temperature of 450° C. or lower in a top gate structure.

Patterning of the ZTO channel layer may be performed using an ion milling method, a plasma dry etching method using a gaseous mixture of Cl₂ and Ar, or a lift-off method.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIGS. 1 to 4 are cross-sectional views of a structure of a thin film transistor according to an exemplary embodiment of the present invention;

FIG. 5 illustrates a process of patterning using an ion milling method according to an exemplary embodiment of the present invention;

FIG. 6 is a diagram showing a composition of a ZTO thin film formed by a low-temperature process found using permutations and combinations according to an exemplary embodiment of the present invention.

FIG. 7 is a graph showing regional composition of a ZTO thin film of FIG. 6;

FIG. 8 is an XRD analysis graph of regional crystal properties of the ZTO thin film of FIG. 6;

FIG. 9 is an XRD analysis graph of regional crystal properties of the ZTO thin film formed at a deposition temperature of 450° C. of FIG. 6;

FIG. 10 is an XRD analysis graph of regional crystal properties of the ZTO thin film formed at a deposition temperature of 600° C. of FIG. 6;

FIG. 11 is a graph of MIS capacitance versus voltage according to the annealing temperature of a gate insulating layer;

FIG. 12 is a transfer plot for a thin film transistor fabricated in Example 1 of the present invention;

FIG. 13 is a transfer plot for a thin film transistor fabricated in Example 2 of the present invention;

FIG. 14 is a graph of results of analyzing current stability of a thin film transistor fabricated in Example 3 of the present invention;

FIG. 15 is a graph of current-voltage characteristics of the thin film transistor fabricated in Example 3 of the present invention according to different voltage application times;

FIG. 16 illustrates results of measuring transmittance of a thin film transistor fabricated in Example 4 of the present invention;

FIG. 17 illustrates an example of use of an amorphous ZTO thin film transistor in a medical transparent display panel;

FIG. 18 illustrates an example of an amorphous ZTO thin film transistor applied to an electronic circuit,

FIG. 19 illustrates an example of an amorphous ZTO thin film transistor used for UV PD;

FIG. 20 illustrates an example of an amorphous ZTO thin film transistor used for a transparent LED;

FIG. 21 illustrates an example of an amorphous ZTO thin film transistor used for a double-sided transparent monitor panel;

FIG. 22 illustrates an example of an amorphous ZTO thin film transistor that is applicable to a panel as a driving device of LCD or OLED;

FIG. 23 illustrates an example of an amorphous ZTO thin film transistor used for a transparent RFID;

FIG. 24 illustrates an example of an amorphous ZTO thin film transistor used for a smart window that functions as both a transparent glass window and a display;

FIG. 25 illustrates an example of an amorphous ZTO thin film transistor used for a head-up display (HUD) of a car, or airplane;

FIG. 26 illustrates an example of an amorphous ZTO thin film transistor used for a head mounted display (HMD); and

FIG. 27 illustrates an example of an amorphous ZTO thin film transistor used for a general-purpose transparent display or a flexible, transparent display.

### DETAILED DESCRIPTION OF EXEMPLARY EMBODIMENTS

The present invention will be described more fully hereinafter with reference to the accompanying drawings, in which exemplary embodiments of the invention are shown. This invention may, however, be embodied in different forms and should not be construed as limited to the exemplary embodiments set forth herein.

A method of fabricating a ZTO thin film according to the present invention includes depositing zinc oxide and tin oxide at a deposition temperature of 450° C. or lower, to form a zinc-tin-oxide (ZTO) thin film, wherein a zinc-to-tin atomic ratio is 4:1 or greater.

Deposition may be performed using a general deposition method, and more preferably, a sputtering method.

The ZTO thin film may be post-annealed at a temperature of 150° C. to 450° C. in order to improve its electrical characteristics.

The composition of zinc and tin in the ZTO thin film may be an atomic ratio of 4:1 or greater. Also, during a low-temperature process performed at a temperature of 300° C. or lower, the ZTO thin film may maintain its amorphous state within a zinc-to-tin atomic ratio ranging from 4:1 to 2:1. Moreover, during a high-temperature process performed at a temperature of 300° C. to 450° C., the ZTO thin film may maintain its amorphous state within a zinc-to-tin atomic ratio ranging from 4:1 to 1:4.

An optimal composition ratio of zinc-to-tin may be confirmed through permutations and combinations. That is, in the permutations and combinations, zinc oxide and tin oxide are deposited on a stationary substrate using a zinc oxide target and a tin oxide target mounted on a sputter. A thin film containing a high composition of each target is obtained close to each target, and a thin film containing a low composition of each target is obtained as distance increases. Consequently, composition of the thin film may sequentially change depending on change in distance. Accordingly, an area is divided at regular intervals, compositions of each region are analyzed, and crystal properties of the thin film are checked to confirm an optimal composition ratio of zinc-to-tin.

For example, compositions of each region are analyzed at vertices between regions using Auger Electron Spectroscopy (AES). Further, crystal properties of each region are analyzed by X-ray diffraction (XRD).

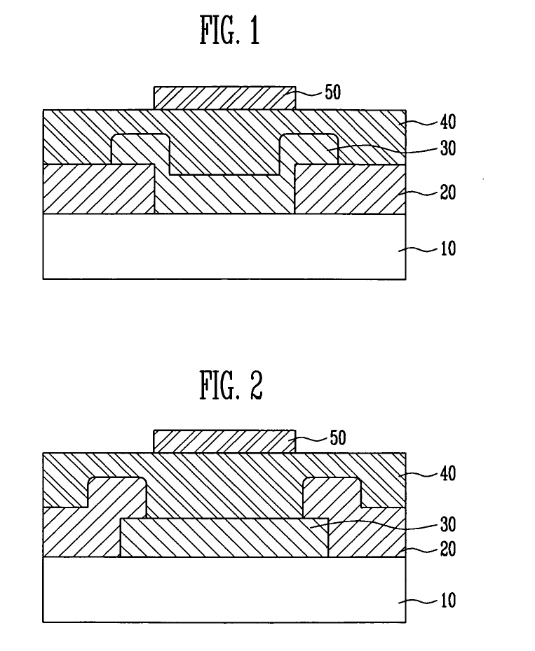

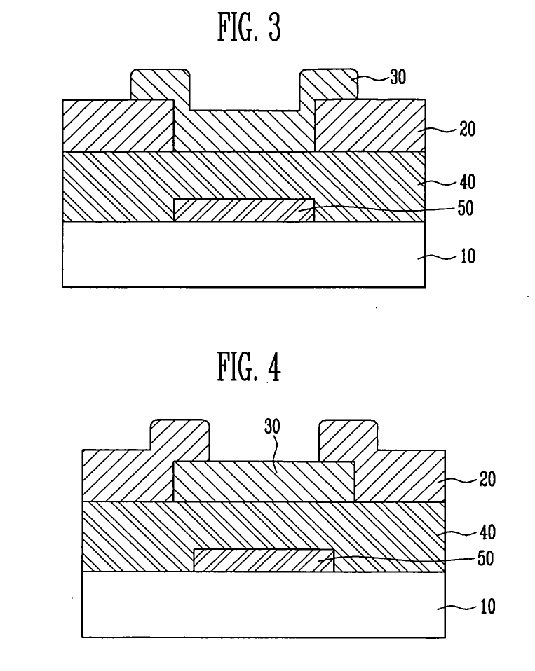

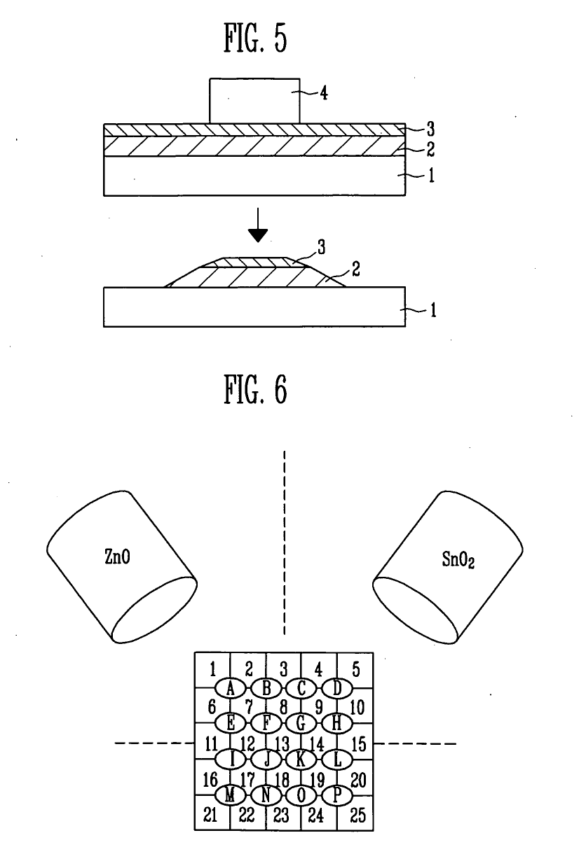

As illustrated in FIGS. 1 to 4, a thin film transistor according to the present invention may be a top gate thin film transistor having a coplanar structure in which source and drain electrodes 20, a channel layer 30, a gate insulating layer 40, and a gate electrode 50 are sequentially stacked on a substrate 10. Alternatively, it may be a top gate thin film transistor having an inverted staggered structure in which the channel layer 30, the source and drain electrodes 20, the gate insulating layer 40 and the gate electrode 50 are sequentially stacked on the substrate 10. Alternatively, it may be a bottom gate thin film transistor having a coplanar structure in which the gate electrode 50, the gate insulating layer 40, the source and drain electrodes 20, and the channel layer 30 are sequentially stacked on the substrate 10. Or, it may be a bottom gate thin film transistor having a staggered structure in which the gate electrode 50, the gate insulating layer 40, the channel layer 30 and the source and drain electrodes 20 are sequentially stacked on the substrate 10.

Each layer will be described in detail with reference to FIG. 1. Referring to FIG. 1, the thin film transistor according to the present invention includes the source and drain electrodes 20, the channel layer 30, the gate insulating layer 40 and the gate electrode 50 on the substrate 10.

Any substrate commonly used in this field may be used as the substrate 10. For example, a glass, metal foil, plastic or silicon substrate may be selected.

The source and drain electrodes 20 formed on the substrate 10 may be formed of a transparent oxide such as ITO, IZO or ZnO:Al(Ga), metal such as Al, Cr, Au, Ag, Ti, etc., or conductive polymer, but there is no restriction here. Also, the source and drain electrodes 20 may have a double-layer structure of the metal and an oxide. The source and drain electrodes 20 may be deposited to a normal thickness using a sputtering method, ALD, CVD, etc., and may be patterned.

The channel layer 30 formed in a channel region on the substrate 10 and the source and drain electrodes 20 is formed by depositing zinc oxide and tin oxide at a deposition temperature of 450° C. or lower so that a zinc-to-tin atomic ratio is 4:1 or greater. While the deposition temperature may be room temperature, it is preferably 150° C. or higher considering device characteristics.

Deposition may be performed using a normal deposition method used in this field, and more preferably, a sputtering method may be employed.

A post-annealing process may be performed on the channel layer at a temperature of 450° C. or lower, and more preferably, 150° C. to 450° C.

The channel layer 30 may be patterned using an ion milling method, a plasma dry etching method employing a gaseous mixture of Cl₂ and Ar, or a lift-off method.

As illustrated in FIG. 5, the ion milling method includes forming a hard mask layer 3 on a ZTO thin film 2 formed on a substrate 1 using Plasma Enhanced Chemical Vapor Deposition (PECVD), patterning the layer using a photoresist pattern 4, etching the hard mask layer 3 using a preferred wet etching method, and patterning the ZTO thin film 2 on which the hard mask layer 3 is not disposed using an ion milling method. Here, the ZTO thin film 2 may be formed of a silicon nitride layer or a silicon oxide layer.

The plasma dry etching method includes dry etching with plasma using a gaseous mixture of Cl₂ and Ar, and removing residue by an O₂ ashing process.

The lift-off method includes forming a lift-off pattern using photoresist. Here, the photoresist is weak at ZTO deposition temperature, and thus may be applied at a temperature lower than 150° C.

The gate insulating layer 40 that at least partially forms an interface with the channel layer 30 may be deposited at a temperature of 450° C. lower using alumina, silicon nitride or silicon oxide. Alumina may be deposited using an atomic layer deposition (ALD) method, a PECVD method or a metal-organic chemical vapor deposition (MOCVD) method, and preferably, the ALD method, at a temperature of 100° C. to 250° C. Moreover, silicon nitride (SiNₓ) or silicon oxide (SiOₓ) may be deposited at a temperature of 150° C. to 450° C. using the PECVD method. In the case of a top gate, the deposition temperature of the gate insulating layer 40 may be within a range that maintains amorphous properties of the ZTO thin film channel layer since the channel layer is deposited in advance.

After the gate insulating layer 40 is formed, a post-annealing process may be performed at a temperature of 150° C. to 450° C. to provide stable characteristics.

The gate electrode formed on the gate insulating layer 40 may be formed of a transparent oxide including ITO, IZO, ZnO:Al(Ga), etc., metal having low resistance such as Ti, Ag, Au, Al, Cr, Al/Cr/Al, Ni, etc., or a conductive polymer, but is not limited hereto. The source and drain electrodes 20 are deposited on the substrate 10 to a normal thickness in this field by sputtering, ALD, Chemical Vaper Deposition (CVD), etc., and then are patterned.

The present invention will be described below in more detail with reference to exemplary embodiments.

### EXPERIMENTAL EXAMPLE

Zinc Oxide to Tin Oxide Composition Ratio and Analysis of Crystal Properties

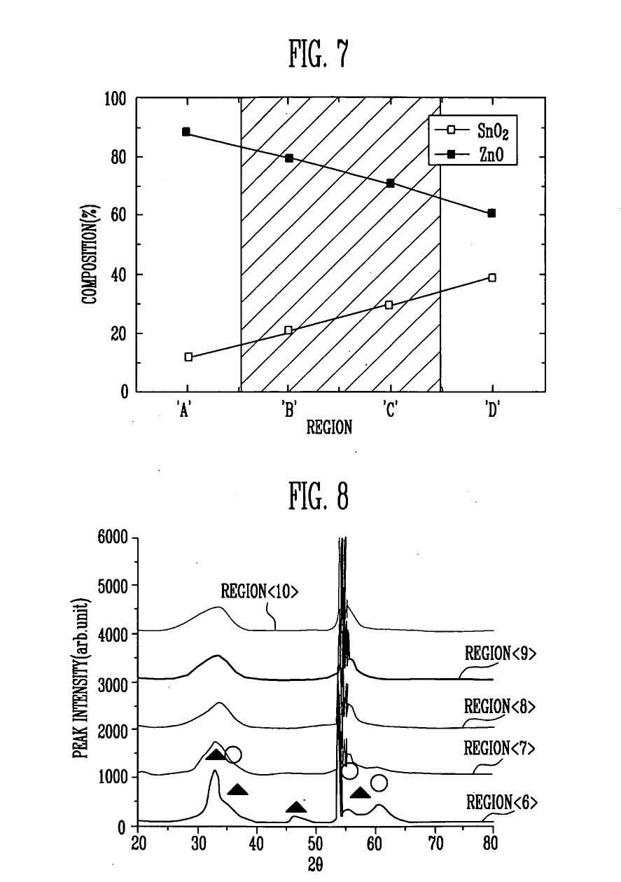

As illustrated in FIG. 6, a zinc-tin-oxide(ZTO) thin film was formed by simultaneously depositing zinc oxide and tin oxide on a stationary substrate at a temperature of 200° C. using a zinc oxide target and a tin oxide target that are mounted on a sputter. Subsequently, the area of the substrate was divided at a regular interval and the composition of the thin film and crystal properties in each region were analyzed. The composition of the thin film was analyzed by AES and the results are illustrated in FIG. 7. Further, the crystal properties in each region were analyzed by XRD and the results are illustrated in FIG. 8.

According to FIGS. 7 and 8, it can be confirmed that an amorphous ZTO thin film was obtained within a zinc-to-tin atomic ratio of 4:1 to 2:1.

Evaluation of Amorphous Properties of ZTO Thin Film Depending on Temperature

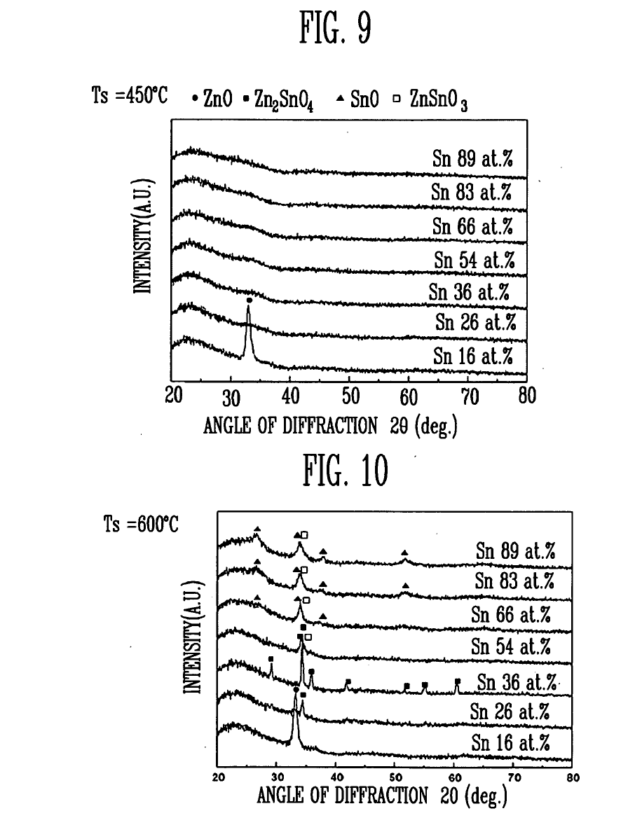

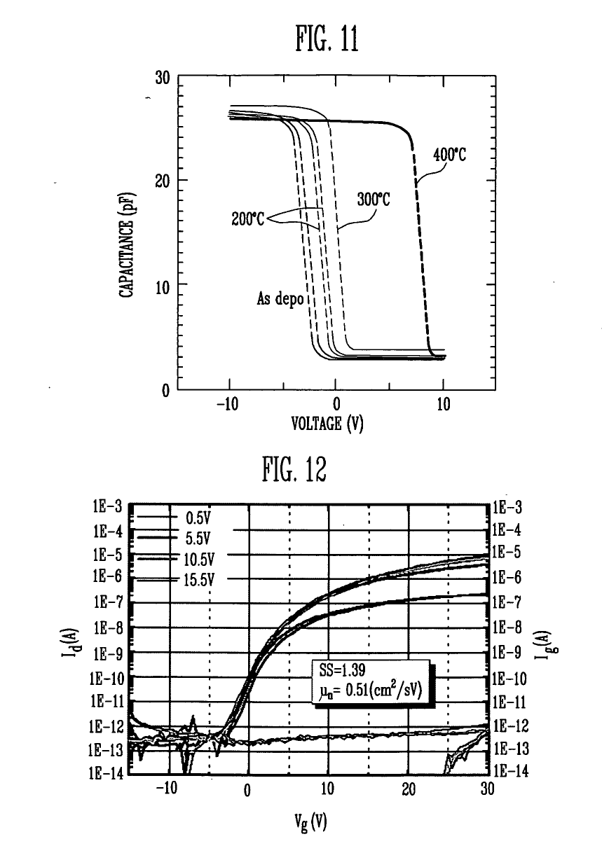

As illustrated in FIG. 6, a zinc-tin-oxide(ZTO) thin films were formed by simultaneously depositing zinc oxide and tin oxide on a stationary substrate at a temperature of 450° C. and 600° C., respectively, using a zinc oxide target and a tin oxide target that are mounted on a sputter Subsequently, the area of the substrate was divided at a regular interval and the composition of the thin film and crystal properties in each region were analyzed. The results are illustrated in FIGS. 9 and 10.

According to FIGS. 9 and 10, it can be confirmed that when tin is 16 at % at a deposition temperature of 450° C., it is in a crystalline state, but beyond this range it is amorphous. In contrast, when the deposition temperature is 600° C., it is generally in a crystalline state.

Evaluation of Characteristics of Gate Insulating Layer According to Annealing Temperature

An insulating layer was deposited to a thickness of 190 nm at a temperature of 150° C. by ALD using alumina. Afterwards, a metal-insulator-semiconductor (MIS) was fabricated using the insulating layer, capacitance versus voltage according to annealing temperature was measured, and the results are illustrated in FIG. 11. According to FIG. 11, it can be confirmed that characteristics of the alumina insulating layer were most stable when annealing was performed at a temperature of 300° C.

### Example 1

Source and drain electrodes were deposited to a thickness of 150 nm on a substrate by sputtering using ITO and then patterned by etching at a temperature of 50° C. using a mixture of phosphoric acid and nitric acid. Afterwards, zinc oxide and tin oxide were deposited on the source and drain electrodes by sputtering at room temperature so that the zinc-to-tin atomic ratio was 3:1, thereby forming a ZTO channel layer to a thickness of 20 nm. Then, the resulting structure was annealed at a temperature of 300° C. for one hour. Subsequently, the channel layer was patterned by dry etching using Cl₂. Then, alumina was deposited on the channel layer at a temperature of 150° C. by ALD method so that a gate insulating layer with a thickness of 190 nm was formed. Subsequently, the gate insulating layer was annealed at a temperature of 300° C. for one hour and patterned by etching using a phosphoric acid solution heated up to a temperature of 120° C. A gate electrode was deposited to a thickness of 150 nm on the gate insulating layer by sputtering using ITO and patterned by etching at a temperature of 50° C. using a mixture of phosphoric acid and nitric acid so that a thin film transistor was fabricated. Characteristics of the obtained transistor were evaluated and the results are illustrated in FIG. 12. As can be confirmed from FIG. 12, SS was equal to 1.39 and mobility was 0.51.

### Example 2

A thin film transistor was fabricated in the same manner as Example 1 except that a deposition temperature was 200° C. when the channel layer was formed. Characteristics of the obtained transistor were evaluated and the results are illustrated in FIG. 13. As can be confirmed from FIG. 13, SS was equal to 0.67 and mobility was 5.08.

Examples 1 and 2 show that although a ZTO channel layer was deposited at a low temperature such as room temperature or 200° C., its characteristics remained intact.

### Example 3

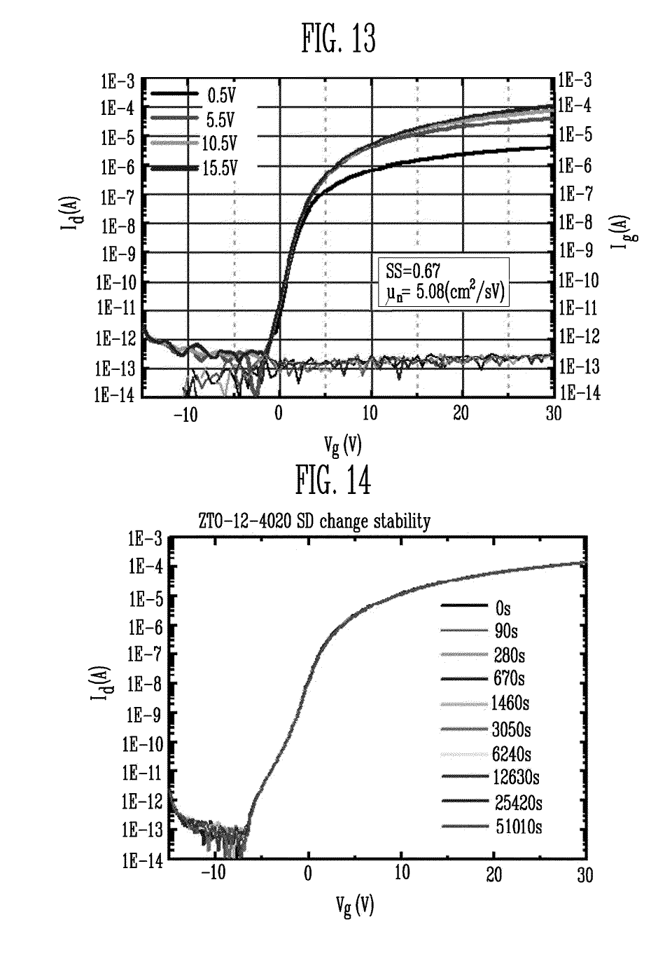

A thin film transistor was fabricated in the same manner as Example 1 except that the zinc-to-tin atomic ratio was 2:1 when the channel layer was formed, and an annealing process was performed at a temperature of 300° C. in an oxygen atmosphere for one hour. Current stability of the obtained transistor was evaluated and the results are illustrated in FIG. 14. Another evaluation was then performed after 15 hours and the results are illustrated in FIG. 15.

As shown in FIG. 14, there was little change in Von and Vt, which indicates excellent current stability. As shown in FIG. 15, a device with excellent reliability exhibiting only a 1% change in current after 15 hours was fabricated.

### Example 4

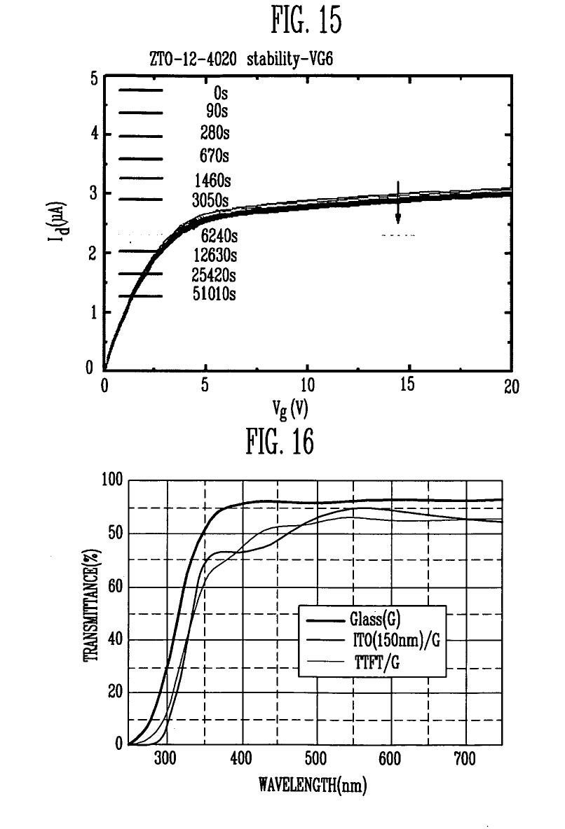

After a gate electrode was deposited to a thickness of 150 nm on a transparent substrate by sputtering using ITO, it was etched at a temperature of 50° C. using a mixture of phosphoric acid and nitric acid and patterned. Afterwards, alumina was deposited on the gate electrode at a temperature of 150° C. by ALD and a gate insulating layer was formed to a thickness of 190 nm. Subsequently, the gate insulating layer was annealed at a temperature of 300° C. for one hour and patterned by etching using a phosphoric acid solution heated up to a temperature of 120° C. Then, zinc oxide and tin oxide were deposited on the gate insulating layer by sputtering at a temperature of 200° C. so that the zinc-to-tin atomic ratio was 3:1. As a result, a ZTO channel layer was formed to a thickness of 20 nm and the resultant structure was annealed at a temperature of 300° C. for one hour. Subsequently, the channel layer was patterned by dry etching with Cl₂. Then, after the source and drain electrodes were deposited to a thickness of 150 nm on the channel layer by sputtering using ITO, the resultant structure was patterned by etching at a temperature of 50° C. using a mixture of phosphoric acid and nitric acid, so that a thin film transistor was fabricated. Transmittance of the obtained transistor was measured and the results are illustrated in FIG. 16. According to FIG. 16, average transmittance was 80% or higher within ultraviolet and infrared regions.

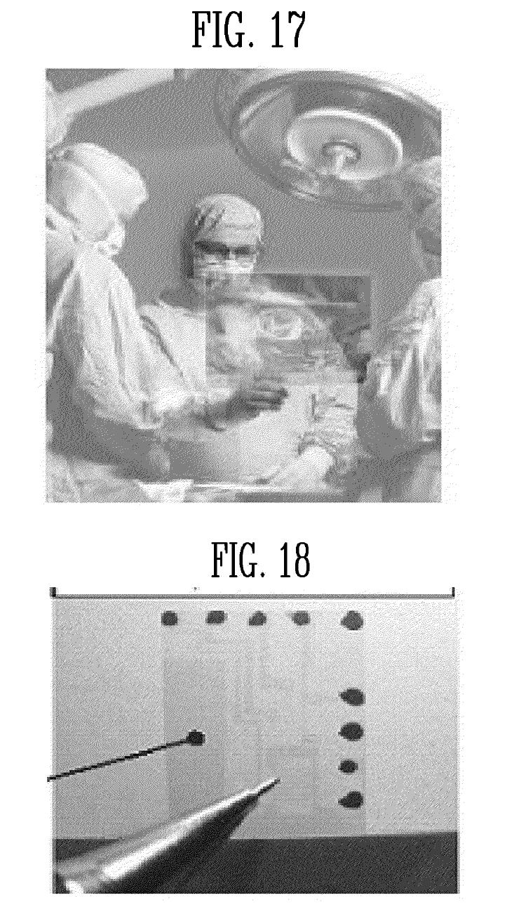

As described above, a thin film transistor employing a ZTO channel layer has numerous applications and may be used to design displays and various transparent circuits such as the examples illustrated in FIGS. 17 to 27.

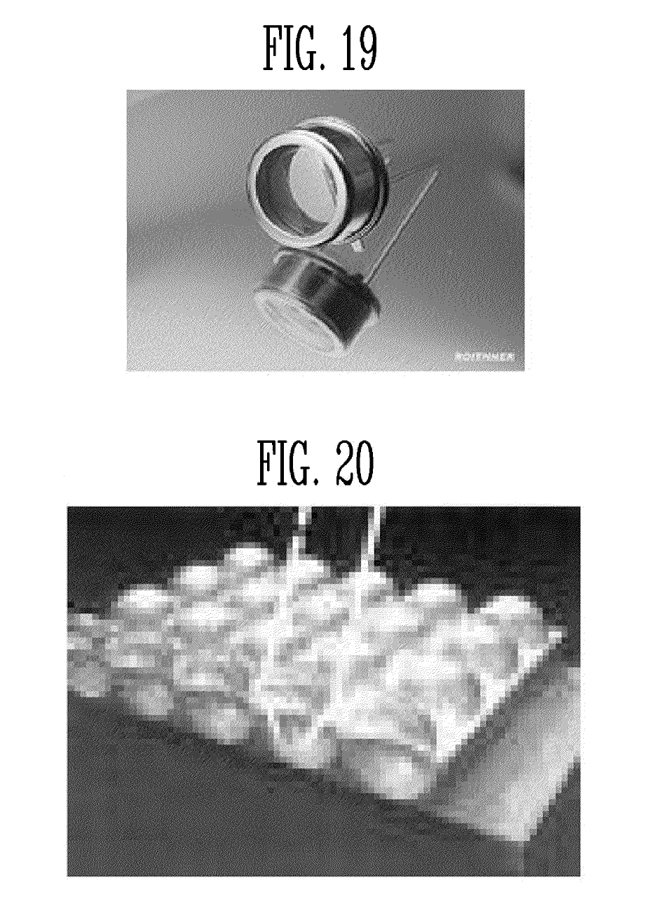

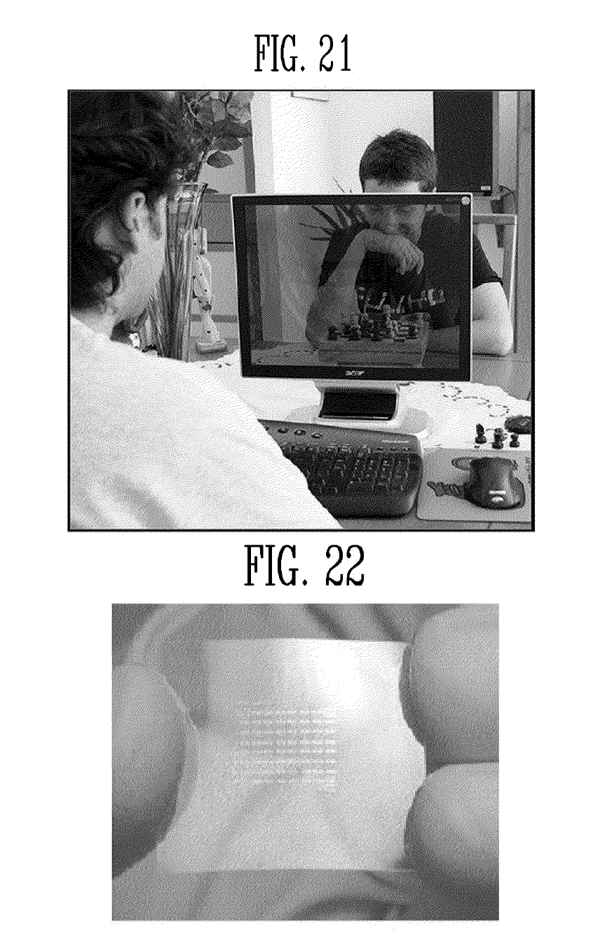

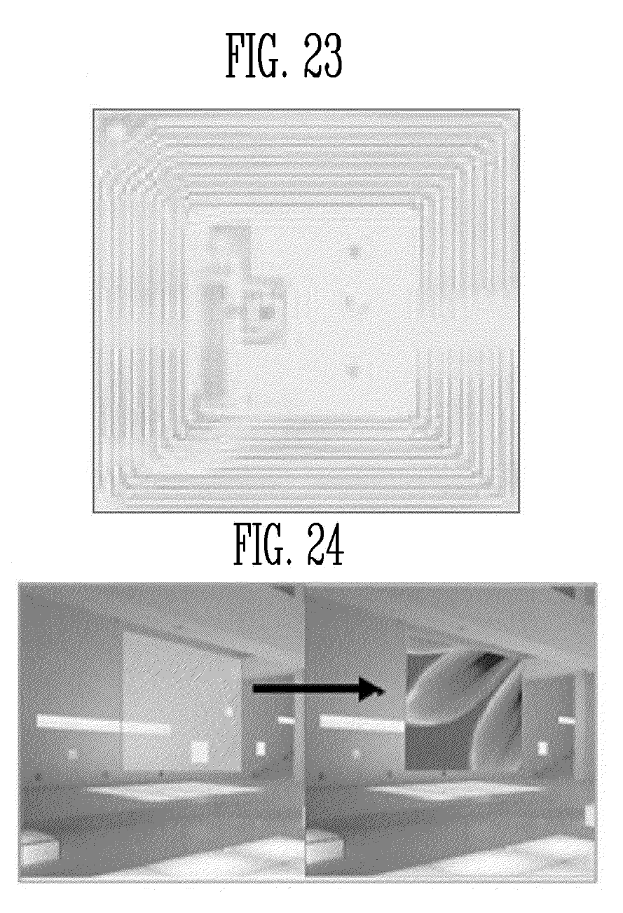

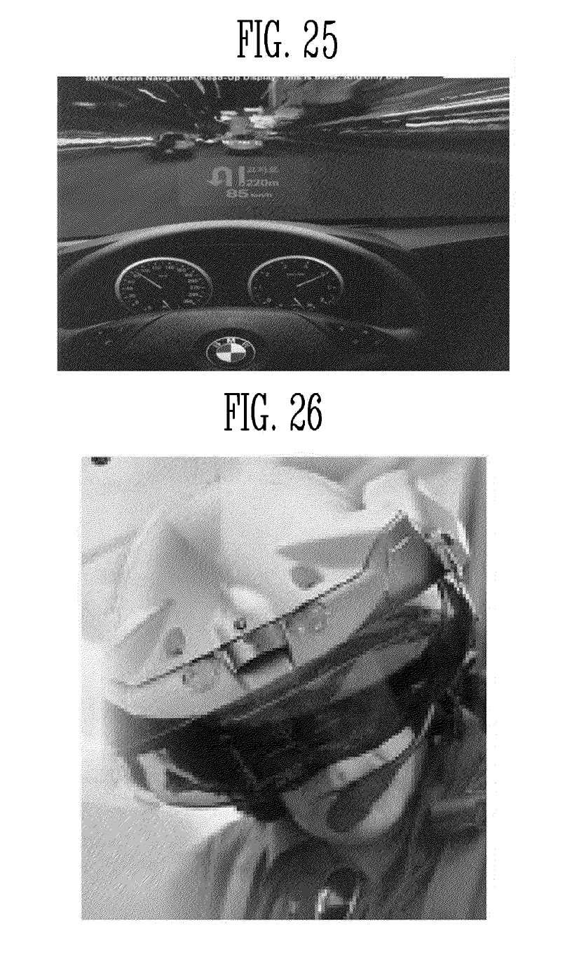

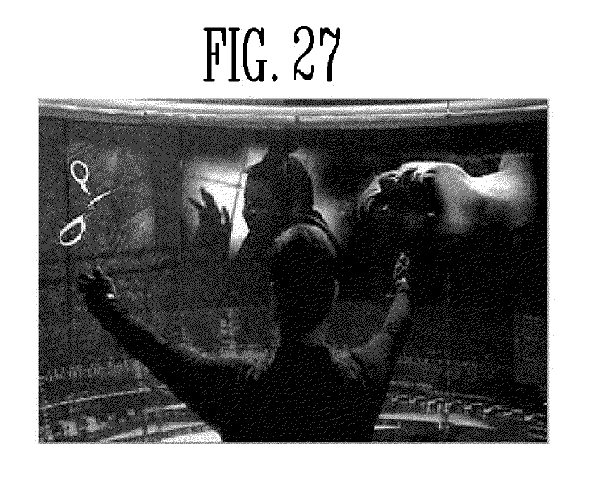

FIG. 17 illustrates use of an amorphous ZTO thin film transistor in a medical transparent display panel, FIG. 18 illustrates use of an amorphous ZTO thin film transistor in an electronic circuit, FIG. 19 illustrates use of an amorphous ZTO thin film transistor in UV PD, FIG. 20 illustrates use of an amorphous ZTO thin film transistor in a transparent LED, FIG. 21 illustrates use of an amorphous ZTO thin film transistor in a double sided transparent monitor panel, FIG. 22 illustrates use of an amorphous ZTO thin film transistor as a driving device of an LCD or OLED panel, FIG. 23 illustrates use of an amorphous ZTO thin film transistor in a transparent RFID tag, FIG. 24 illustrates use of an amorphous ZTO thin film in a smart window that functions as both a transparent glass window and a display, FIG. 25 illustrates use of an amorphous ZTO thin film in a head-up display (HUD) of a car or airplane, FIG. 26 illustrates use of an amorphous ZTO thin film in a head mounted display (HMD), and FIG. 27 illustrates use of an amorphous ZTO thin film in a general-purpose transparent display or a flexible, transparent display.

The present invention exhibits the following effects.

First, since the present invention can be implemented by a low-temperature (such as room temperature) process performed, and an amorphous ZTO thin film can be fabricated even at a deposition temperature of 450° C., the present invention can increase the usability of low-temperature substrates and cheaper glass substrates.

Second, according to the present invention, an amorphous ZTO thin film is used as a channel layer so that device uniformity is considerably increased.

Third, since a gate insulating layer together with a channel layer are formed at a low-temperature of 450° C. or lower through an optimized process, a thin film transistor exhibiting high-reliability can be fabricated.

Fourth, a thin film transistor exhibiting high-transparency and high-reliability can be fabricated and employed in various devices including displays.

Fifth, in the present invention, characteristics of a transparent electronic device can be ensured without using costly indium or gallium, thereby providing an alternative to conventional channel materials and processes.

In the drawings and specification, there have been disclosed typical exemplary embodiments of the invention and, although specific terms are employed, they are used in a generic and descriptive sense only and not for purposes of limitation. As for the scope of the invention, it is to be set forth in the following claims. Therefore, it will be understood by those of ordinary skill in the art that various changes in form and details may be made therein without departing from the spirit and scope of the present invention as defined by the following claims.

1. A method of fabricating a ZTO thin film, comprising:
depositing zinc oxide and tin oxide at a deposition temperature of 450° C. or lower to form an amorphous zinc-tin-oxide (ZTO) thin film, wherein a zinc-to-tin atomic ratio is 4:1 or greater.

2. The method of claim 1, further comprising post-annealing the ZTO thin film at a temperature of 150° C. to 450° C.

3. The method of claim 1, wherein the zinc-to-tin atomic ratio is 4:1 to 2:1 at a deposition temperature of 300° C. or lower and 4:1 to 1:4 at a deposition temperature of 300° C. to 450° C.

4. A thin film transistor, comprising:
source and drain electrodes, a channel layer, a gate insulating layer and a gate electrode that are formed on a substrate, wherein the channel layer is an amorphous ZTO thin film formed by depositing zinc oxide and tin oxide at a deposition temperature of 450° C. or lower so that a zinc-to-tin atomic ratio is 4:1 or greater.

5. The transistor of claim 4, wherein the thin film transistor has:
a top gate coplanar structure in which source and drain electrodes, a channel layer, a gate insulating layer, and a gate electrode are sequentially formed on a substrate;
a top gate staggered structure in which a channel layer, source and drain electrodes, a gate insulating layer and a gate electrode are sequentially formed on a substrate;
a bottom gate coplanar structure in which a gate electrode, a gate insulating layer, source and drain electrodes, and a channel layer are sequentially formed on a substrate; or
a bottom gate staggered structure in which a gate electrode, a gate insulating layer, a channel layer and source and drain electrodes are sequentially formed on a substrate.

6. The transistor of claim 4, wherein the gate insulating layer is formed of alumina, silicon nitride or silicon oxide.

7. The transistor of claim 5, wherein the gate insulating layer is formed at a temperature of 450° C. or lower when the transistor has a top gate structure.

8. The transistor of claim 5, wherein the gate insulating layer is post-annealed at a temperature of 150° C. to 450° C.

9. A method of fabricating a thin film transistor in which source and drain electrodes, a channel layer, a gate insulating layer, and a gate electrode are formed on a substrate, comprising:
depositing zinc oxide and tin oxide at a deposition temperature of 450° C. or lower so that a zinc-to-tin atomic ratio is 4:1 or greater, to form an amorphous ZTO channel layer; and
patterning the ZTO channel layer.

10. The method of claim 9, wherein the gate insulating layer is at least partially in contact with the ZTO channel layer, is formed of alumina, silicon nitride or silicon oxide, and is formed at a temperature of 450° C. or lower when the transistor has a top gate structure.

11. The method of claim 9, wherein the patterning of the ZTO channel layer is performed using an ion milling method comprises:
forming a hard mask layer on the ZTO channel layer using a PECVD method;
patterning using photoresist;
etching the hard mask layer by a preferred wet etching; and
patterning ZTO thin film on which no hard mask exists by ion milling.

12. The method of claim 9, wherein patterning of the ZTO channel layer is performed by plasma dry etching using a gaseous mixture of Cl₂ and Ar, and residue from dry etching is removed by O₂ ashing.

13. The method of claim 9, wherein patterning of the ZTO channel layer is performed using a lift-off pattern as photoresist that is applicable at a temperature lower than 150° C.
